(19) United States
(12) Patent Application Publication
(10) Pub. No.: US 2026/0371930 A1
(43) Pub. Date: Nov. 19, 2026

(54) ULTRASONIC TRANSDUCER AND DISPLAY PANEL

(71) Applicants: Beijing BOE Technology Development Co., Ltd., Beijing (CN); BOE Technology Group Co., Ltd., Beijing (CN)

(72) Inventors: Yanling HAN, Beijing (CN); Lei WANG, Beijing (CN); Yunke QIN, Beijing (CN); Jianqing RAN, Beijing (CN); Jiakui YAN, Beijing (CN); Yonggang CAO, Beijing (CN); Yaqian JI, Beijing (CN); Yue GOU, Beijing (CN)

(21) Appl. No.: 19/477,441

(22) PCT Filed: Oct. 31, 2023
(86) PCT No.: PCT/CN2023/128861

§ 371 Date: Oct. 21, 2025

(51) Int. Cl. H10N 30/30; H10D 86/40; H10D 86/60; H10N 30/87; H10N 39/00

(52) U.S. Cl. CPC H10N 30/302; H10D 86/441; H10D 86/60; H10N 30/872; H10N 39/00

(57) ABSTRACT

An ultrasonic transducer and a display panel are disclosed. The ultrasonic transducer includes: a driving backplane; a plurality of transducer units on the driving backplane; each transducer unit including a first electrode disposed on the driving backplane and electrically connected with the driving backplane, a second electrode disposed on a side of the first electrode facing away from the driving backplane, a plurality of resonant cavities which are spaced apart from each other between the first electrode and the second electrode, and a diaphragm disposed between the resonant cavity and the second electrode.

### CROSS REFERENCE TO RELATED APPLICATIONS

This application is a national phase entry under 35 U.S.C. § 371 of International Application No. PCT/CN2023/128861, filed on Oct. 31, 2023, the entire content of which is incorporated herein by reference.

### TECHNICAL FIELD

The disclosure relates to the field of sensing technology, and particularly to an ultrasonic transducer and a display panel.

### BACKGROUND

Fingerprint recognition technology is widely applied in mobile terminals such as mobile phones and tablet computers, as well as in security protection fields such as access control systems and safes. At present, the main implementation methods of fingerprint acquisition in fingerprint recognition technology include optical, capacitive, and ultrasonic imaging methods. Among them, ultrasonic fingerprint recognition technology has 3D characteristics, and does not require the user's finger to touch the fingerprint acquisition device, which can improve recognition security and user experience.

Current ultrasonic fingerprint recognition technologies typically employ bulk piezoelectric ultrasonic transducers. Conventional bulk piezoelectric materials, such as piezoelectric ceramics, suffer from complex manufacturing processes, high-temperature requirements, and difficulties in fabricating high-precision arrays. Therefore, to achieve fingerprint recognition with micron-level accuracy, thin-film bulk piezoelectric materials should be used. However, these materials significantly compromise piezoelectric performance, thereby limiting the transmission and reception capabilities of ultrasonic transducers.

Compared with bulk piezoelectric ultrasonic transducers, Micromachined Ultrasonic Transducers (MUTs) have simpler processes and excellent transmitting/receiving performance, and have become a development trend. MUTs include Piezoelectric Micromachined Ultrasonic Transducers (PMUTs) and Capacitive Micromachined Ultrasonic Transducers (CMUTs). CMUTs do not require piezoelectric materials, and can be fabricated using conventional semiconductor processes and materials, which is conducive to cost control.

At present, CMUTs are usually fabricated using silicon-based processes, which makes it difficult to achieve large-area devices. Fabricating CMUTs on a glass substrate or a PI (Polyimide) substrate is conducive to realizing large-area devices. However, the process accuracy is relatively low, which easily leads to a decline in device performance.

### SUMMARY

The disclosure provides an ultrasonic transducer and a display panel, aiming to improve the performance of the ultrasonic transducer.

In a first aspect, the disclosure provides an ultrasonic transducer, including: a driving backplane; a plurality of transducer units on the driving backplane; each transducer unit including a first electrode disposed on the driving backplane and electrically connected with the driving backplane, a second electrode disposed on a side of the first electrode facing away from the driving backplane, a plurality of resonant cavities which are spaced apart from each other between the first electrode and the second electrode, and a diaphragm disposed between the resonant cavity and the second electrode.

In the ultrasonic transducer provided by the disclosure, in the transducer unit, at least some of the plurality of resonant cavities have different sizes.

In the ultrasonic transducer provided by the disclosure, the plurality of resonant cavities include at least one first resonant cavity, at least one second resonant cavity, and at least one third resonant cavity; a size of the first resonant cavity is larger than a size of the second resonant cavity, and the size of the second resonant cavity is larger than a size of the third resonant cavity.

In the ultrasonic transducer provided by the disclosure, any two resonant cavities among the first resonant cavities and the third resonant cavities are arranged in pairs at both sides of the second resonant cavity.

In the ultrasonic transducer provided by the disclosure, in the transducer unit, the plurality of resonant cavities are arranged in an array with three rows and three columns; at least a resonant cavity located at a center of the array is the second resonant cavity.

In the ultrasonic transducer provided by the disclosure, a size difference between the second resonant cavity and the first resonant cavity is less than or equal to 0.6 μm; a size difference between the third resonant cavity and the second resonant cavity is less than or equal to 0.6 μm.

In the ultrasonic transducer provided by the disclosure, in the transducer unit, the plurality of resonant cavities are arranged in a plurality of rows, with resonant cavities in two adjacent rows being arranged in a staggered manner.

In the ultrasonic transducer provided by the disclosure, in the transducer unit, the plurality of resonant cavities are of a same size, and the plurality of resonant cavities are arranged in an array.

In the ultrasonic transducer provided by the disclosure, in the transducer unit, the plurality of resonant cavities are of a same size, and the resonant cavities are arranged in a plurality of rows, with resonant cavities in two adjacent rows being arranged in a staggered manner.

In the ultrasonic transducer provided by the disclosure, a spacing between adjacent resonant cavities within a same transducer unit is smaller than a spacing between resonant cavities located respectively in two adjacent transducer units.

In the ultrasonic transducer provided by the disclosure, the second electrode includes a plurality of second electrode sub-portions which are spaced apart from each other; the second electrode sub-portions are electrically connected via a first connection line; one of the plurality of second electrode sub-portions corresponds to one of the plurality of resonant cavities; an orthographic projection of the second electrode sub-portion on the driving backplane is located within an orthographic projection of a corresponding resonant cavity on the driving backplane.

In the ultrasonic transducer provided by the disclosure, the second electrode includes a plurality of connection regions; second electrode sub-portions within a same connection region are electrically connected with each other, and second electrode sub-portions in different connection regions are insulated from each other; the second electrode sub-portions within the same connection region are electrically connected with a same first signal line, to allow a same signal to be provided to the second electrode sub-portions within that connection region.

In the ultrasonic transducer provided by the disclosure, in the transducer unit, the first electrode is formed across an entire surface.

In the ultrasonic transducer provided by the disclosure, the first electrode includes a plurality of first electrode sub-portions which are spaced apart from each other; one of the first electrode sub-portions corresponds to one of the plurality of resonant cavities; an orthographic projection of the resonant cavity on the driving backplane is located within an orthographic projection of a corresponding first electrode sub-portion on the driving backplane; the plurality of first electrode sub-portions of the first electrode are connected to a same second signal line, to allow a same signal to be provided to the plurality of first electrode sub-portions of the first electrode.

In the ultrasonic transducer provided by the disclosure, the first electrode sub-portions are electrically connected via a second connection line; an extension direction of the first connection line and an extension direction of the second connection line intersect with each other.

In the ultrasonic transducer provided by the disclosure, in the transducer unit, the plurality of resonant cavities are arranged in a plurality of rows and a plurality of columns; the first connection line connects second electrode sub-portions located in a same row along a row direction of the plurality of resonant cavities; the second connection line connects the first electrode sub-portions located in a same column along a column direction of the plurality of resonant cavities.

In the ultrasonic transducer provided by the disclosure, in the transducer unit, the plurality of resonant cavities are arranged in a plurality of rows and a plurality of columns; the first connection line connects second electrode sub-portions located in a same row along a row direction of the plurality of resonant cavities, and connects second electrode sub-portions located in a same column along a column direction of the plurality of resonant cavities; the second connection line connects, along a diagonal direction of the plurality of resonant cavities, first electrode sub-portions arranged in a direction parallel to the diagonal direction.

In the ultrasonic transducer provided by the disclosure, in the transducer unit, the plurality of resonant cavities are arranged in a plurality of rows and a plurality of columns; the first connection line connects, along a diagonal direction of the plurality of resonant cavities, second electrode sub-portions arranged in a direction parallel to the diagonal direction; the second connection line connects first electrode sub-portions located in a same row along a row direction of the plurality of resonant cavities, and connects first electrode sub-portions located in a same column along a column direction of the plurality of resonant cavities.

In the ultrasonic transducer provided by the disclosure, the driving backplane includes a plurality of driving circuits; one of the plurality of driving circuits corresponds to one of the plurality of transducer units, and the driving circuit is electrically connected with a corresponding transducer unit; the driving circuit includes a thin film transistor.

In the ultrasonic transducer provided by the disclosure, the driving backplane further includes a base substrate, disposed on a side of the driving circuit facing away from the plurality of transducer units; the base substrate is made of glass or polyimide.

In a second aspect, the disclosure provides a display panel including the ultrasonic transducer according to any of the foregoing aspects.

In a third aspect, the disclosure provides a display device including the display panel according to any of the foregoing aspects.

In a fourth aspect, the disclosure provides a method of manufacturing an ultrasonic transducer, including: fabricating, on a driving backplane, a plurality of first electrodes electrically connected with the driving backplane; fabricating diaphragms and resonant cavities on a side of the first electrode facing away from the driving backplane; where the resonant cavity is disposed between the diaphragm and the first electrode; an orthographic projection of the first electrode on the driving backplane overlaps with orthographic projections of the resonant cavities on the driving backplane; fabricating a plurality of second electrodes on a side of the diaphragms facing away from the resonant cavities; where one of the plurality of second electrode corresponds to one of the plurality of first electrodes; an orthographic projection of the second electrode on the driving backplane overlaps with an orthographic projection of a corresponding first electrode on the driving backplane.

Beneficial effects based on the disclosure are as follows.

The disclosure provides an ultrasonic transducer and a display panel, where the ultrasonic transducer includes a driving backplane and transducer units. The transducer units are disposed on the driving backplane. Each transducer unit includes a first electrode disposed on the driving backplane and electrically connected with the driving backplane, a second electrode disposed on a side of the first electrode facing away from the driving backplane, a plurality of resonant cavities which are spaced apart from each other and disposed between the first electrode and the second electrode, and a diaphragm disposed between the resonant cavity and the second electrode. In the ultrasonic transducer provided herein, a plurality of cavities are arranged between the first electrode and the second electrode of each transducer unit, and correspondingly each transducer unit has a plurality of diaphragms corresponding to the cavities. During the ultrasonic transmitting and receiving phases, the plurality of diaphragms in each transducer unit vibrate together to transmit or receive ultrasonic waves. The central frequencies of the plurality of diaphragms are close, with an overlapping frequency range of −3 dB, and acoustic field superposition can increase signal strength and bandwidth. Compared with setting one cavity in each transducer unit, this arrangement can reduce the impact of process variations on the performance of the ultrasonic transducer.

### BRIEF DESCRIPTION OF FIGURES

In order to more clearly illustrate the technical solutions of the embodiments of the disclosure, the drawings required for describing the embodiments of the disclosure are briefly introduced below. Obviously, the drawings described below are only some embodiments of the disclosure. For those of skilled in the art, other drawings can also be obtained based on these drawings without creative efforts.

FIG. 1 is a first cross-sectional view of a CMUT according to embodiments of the disclosure.

FIG. 2A is a schematic diagram of a driving circuit of a CMUT according to embodiments of the disclosure.

FIG. 2B is a timing chart for driving a CMUT according to embodiments of the disclosure.

FIG. 3 is a cross-sectional view of a CMUT in the related art.

FIG. 4A is a first top view of a CMUT according to embodiments of the disclosure;

FIG. 4B is a top view of a CMUT in the related art.

FIG. 5 is a second top view of a CMUT according to embodiments of the disclosure.

FIG. 6A is a third top view of a CMUT according to embodiments of the disclosure.

FIG. 6B is a fourth top view of a CMUT according to embodiments of the disclosure.

FIG. 6C is a fifth top view of a CMUT according to embodiments of the disclosure.

FIG. 6D is a sixth top view of a CMUT according to embodiments of the disclosure.

FIG. 7A is a seventh top view of a CMUT according to embodiments of the disclosure.

FIG. 7B is an eighth top view of a CMUT according to embodiments of the disclosure.

FIG. 7C is a ninth top view of a CMUT according to embodiments of the disclosure.

FIG. 7D is a tenth top view of a CMUT according to embodiments of the disclosure.

FIG. 8 is an eleventh top view of a CMUT according to embodiments of the disclosure.

FIG. 9A is a second cross-sectional view of a CMUT according to embodiments of the disclosure.

FIG. 9B is a twelfth top view of a CMUT according to embodiments of the disclosure.

FIG. 10A is a thirteenth top view of a CMUT according to embodiments of the disclosure;

FIG. 10B is a fourteenth top view of a CMUT according to embodiments of the disclosure.

FIG. 10C is a fifteenth top view of a CMUT according to embodiments of the disclosure.

FIG. 11A is a third cross-sectional view of a CMUT according to embodiments of the disclosure.

FIG. 11B is a sixteenth top view of a CMUT according to embodiments of the disclosure.

FIG. 12 is a seventeenth top view of a CMUT according to embodiments of the disclosure.

FIG. 13 is an eighteenth top view of a CMUT according to embodiments of the disclosure.

FIG. 14 is a flowchart of a method for manufacturing an ultrasonic transducer according to embodiments of the disclosure.

### DETAILED DESCRIPTION

In order to make the aforementioned objectives, features, and advantages of the disclosure more comprehensible, detailed explanations are provided below with reference to the accompanying drawings and embodiments. It should be understood, however, that the exemplary embodiments may be implemented in various forms and should not be construed as limited to the embodiments set forth herein. Rather, these embodiments are provided to ensure that the disclosure is thorough and complete, and to fully convey the concepts of the exemplary embodiments to those skilled in the art. In the drawings, the same reference numerals denote the same or similar structures, and repeated descriptions thereof are omitted. The terms indicating positions and directions described in the disclosure are illustrated based on the accompanying drawings but may be adjusted as needed, and all such adjustments fall within the protection scope of the disclosure. The drawings in the disclosure are merely schematic illustrations of relative positional relationships and do not represent actual proportions.

Fingerprint recognition technology is widely applied in mobile terminals such as mobile phones and tablet computers, as well as in security protection fields such as access control systems and safes. At present, the main implementation methods of fingerprint acquisition in fingerprint recognition technology include optical, capacitive, and ultrasonic imaging methods. Among them, ultrasonic fingerprint recognition technology has 3D characteristics, and does not require the user's finger to touch the fingerprint acquisition device, which can improve recognition security and user experience.

Current ultrasonic fingerprint recognition technologies typically employ bulk piezoelectric ultrasonic transducers. Conventional bulk piezoelectric materials, such as piezoelectric ceramics, suffer from complex manufacturing processes, high-temperature requirements, and difficulties in fabricating high-precision arrays. Therefore, to achieve fingerprint recognition with micron-level accuracy, thin-film bulk piezoelectric materials should be used. However, these materials significantly compromise piezoelectric performance, thereby limiting the transmission and reception capabilities of ultrasonic transducers.

Compared with bulk piezoelectric ultrasonic transducers, Micromachined Ultrasonic Transducers (MUTs) have simpler processes and excellent transmitting/receiving performance, and have become a development trend. MUTs include Piezoelectric Micromachined Ultrasonic Transducers (PMUTs) and Capacitive Micromachined Ultrasonic Transducers (CMUTs). CMUTs do not require piezoelectric materials, and can be fabricated using conventional semiconductor processes and materials, which is conducive to cost control.

At present, CMUTs are usually fabricated on silicon substrates. However, silicon-based semiconductor processes make it difficult to achieve large-area devices. Fabricating CMUTs based on display semiconductor processes using glass substrates or PI (Polyimide) substrates is conducive to realizing large-area devices.

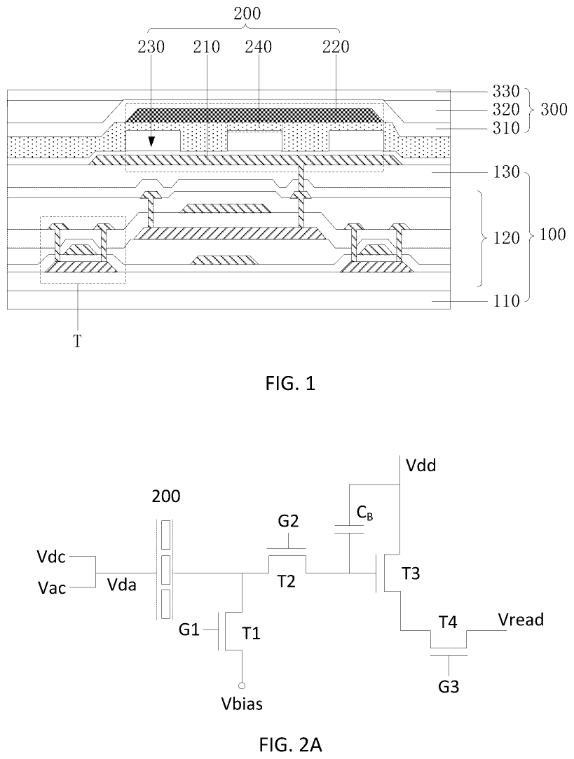

FIG. 1 is a first cross-sectional view of a CMUT according to embodiments of the disclosure.

In the embodiment of the disclosure, as shown in FIG. 1, the CMUT includes a driving backplane 100 and a transducer unit(s) 200.

The driving backplane 100 is located at the bottom of the CMUT, used for supporting and carrying the transducer unit(s) 200, and also used to drive the transducer unit(s) 200 to vibrate during the ultrasonic transmitting phase to emit ultrasonic waves, as well as to receive the current signals converted from ultrasonic waves during the ultrasonic receiving phase, and perform signal acquisition. As shown in FIG. 1, the driving backplane 100 includes a base substrate 110 and a driving circuit layer 120 disposed on the base substrate 110.

The base substrate 110 is used for supporting and carrying the driving circuit layer 120 disposed on the base substrate 110. In specific implementations, the base substrate 110 may be fabricated using substrate materials commonly used in display semiconductor processes. For example, in some embodiments, the base substrate 110 may be fabricated from rigid materials, such as glass. In some embodiments, the base substrate 110 may be fabricated from flexible materials, such as Polyimide (PI), and is not limited thereto.

The driving circuit layer 120 is provided with driving circuit(s), and the transducer unit 200(s) is electrically connected with the driving circuit(s) to realize transmitting/receiving control of ultrasonic waves and signal acquisition. In specific implementations, the driving circuit layer 120 may include a plurality of driving circuits. The CMUT may include a plurality of transducer units, with one driving circuit corresponding to one transducer unit 200, and the transducer unit 200 electrically connected with a corresponding driving circuit. One driving circuit may include at least one Thin Film Transistor (TFT) T to form a TFT driving circuit. The TFT driving circuit may be fabricated using Low-Temperature Poly-Silicon (LTPS) TFT technology, oxide semiconductor TFT technology, or Low-Temperature Polycrystalline Oxide (LTPO) technology. The specific fabrication process of the TFT driving circuit is already very mature in the array substrate fabrication process in the display semiconductor field. In specific implementations, reference can be made to the related processes for fabricating array substrates in display semiconductor processes, which will not be repeated herein.

The transducer unit(s) 200 is disposed on the driving backplane 100. Specifically, the transducer unit(s) 200 is disposed on the side of the driving circuit layer 120 facing away from the base substrate 110. As shown in FIG. 1, the transducer unit 200 includes a first electrode 210 disposed on the driving backplane 100 and electrically connected with the driving backplane 100, a second electrode 220 disposed at a side of the first electrode 210 facing away from the driving backplane 100, a plurality of resonant cavities 230 which are spaced apart from each other and are disposed between the first electrode 210 and the second electrode 220, and a diaphragm 240 disposed between the resonant cavity 230 and the second electrode 220. In specific implementations, an orthographic projection of the second electrode 220 on the driving backplane 100 may be located within an orthographic projection of the first electrode 210 on the driving backplane; and orthographic projections of the plurality of resonant cavities 230 between the first electrode 210 and the second electrode 220 on the driving backplane 100 may be located within the orthographic projection of the first electrode 210 on the driving backplane 100. An orthographic projection of the diaphragm 240 on the driving backplane 100 completely coincides with the orthographic projection of the resonant cavity 230 on the driving backplane. The diaphragm 240 may be of a single-layer structure or a multi-layer structure, which is not limited thereto. In specific implementations, the material of the diaphragm 240 may include at least one of Low-Temperature Poly-Silicon, silicon nitride (SiN), or silicon dioxide (SiO₂), which is not limited thereto.

During the ultrasonic transmitting phase, both a DC signal and an AC signal are applied between the first electrode 210 and the second electrode 220, so that the diaphragm 240 between the first electrode 210 and the second electrode 220 vibrates with changes in the alternating electric field to emit ultrasonic waves. During the ultrasonic receiving phase, only a DC signal is applied between the first electrode 210 and the second electrode 220, so that the diaphragm 240 remains balanced. Under the action of ultrasonic waves, the diaphragm layer 240 generates vibration displacement, thereby changing the capacitance between the first electrode 210 and the second electrode 220 to receive ultrasonic signals.

In the embodiment of the present invention, the ultrasonic transducer includes at least one transducer unit 200. When the ultrasonic transducer includes a plurality of transducer units 200, the first electrode 210 of each transducer unit 200 may be disposed in the same film layer, the second electrode 220 of each transducer unit 200 may be disposed in the same film layer, and the diaphragm 240 of each transducer unit 200 may be disposed in the same film layer.

Specifically, after completing the driving circuit layer 120 of the driving backplane 100, a first planarization layer 130 may be formed on a side of the driving circuit layer 120 facing away from the base substrate 110. The first planarization layer 130 may protect the driving circuits of the driving circuit layer 120 and form a flat surface on the side of the driving circuit layer 120 facing away from the base substrate 110, facilitating subsequent fabrication of the transducer unit 200. Then, by sputter deposition and other processes, a first conductive layer is formed on the side of the planarization layer 130 facing away from the driving circuit layer 120, and the first conductive layer is patterned by exposure, development, etching, and other processes to form a plurality of independent and mutually insulated first electrodes 210. Each first electrode 210 may be electrically connected with the driving circuit lines in the driving circuit layer 120 through vias running through the first planarization layer 130. After fabricating the first electrode 210, an insulating layer covering the first electrode 210 may be formed on the side of the first electrode 210 facing away from the driving backplane by chemical vapor deposition or other processes, for insulating and protecting the first electrode 210.

The resonant cavities 230 may be fabricated by an etching sacrificial layer process. Specifically, after forming the insulating layer covering the first electrode 210, a metal sacrificial layer may be formed on the side of the insulating layer facing away from the first electrode 210 by sputter deposition or other processes, and the metal sacrificial layer is patterned by exposure, development, etching, and other processes to form a plurality of metal sacrificial portions which are spaced apart from each other, each metal sacrificial portion corresponding to one resonant cavity 230. Orthographic projections of at least two metal sacrificial portions on the driving backplane 100 are located within the orthographic projection of a same first electrode 210 on the driving backplane 100. After the metal sacrificial portions are fabricated, a diaphragm layer is deposited across the side of the metal sacrificial portions facing away from the first electrode 210 by chemical vapor deposition or other processes. Then, openings are formed in the diaphragm layer at positions corresponding to the respective metal sacrificial portions, running through the diaphragm layer and exposing the respective metal sacrificial portions. By filling the openings with etching solution, the metal sacrificial portions are etched, and a plurality of resonant cavities 230 are formed in the regions where etching for the metal sacrificial portions is completed, and diaphragms 240 are formed in the parts, corresponding to the resonant cavities 230, of the diaphragm layer. The resonant cavities 230 are spaced apart from each other by the diaphragm layer between them.

After the diaphragms 240 and the resonant cavities 230 are fabricated, a second conductive layer may be formed on the side of the diaphragm layer facing away from the first electrode 210 by sputter deposition or other processes, and the second conductive layer is patterned by exposure, development, etching, and other processes to form a plurality of independent and mutually insulated second electrodes 220. Each second electrode 220 corresponds to one first electrode 210, and an orthographic projection of the second electrode 220 on the driving backplane 100 is located within the orthographic projection of the corresponding first electrode 210 on the driving backplane 100.

In some embodiments, after the second electrodes 220 are fabricated, an insulating protection layer 300 covering the second electrodes 220 may be formed on the side of the second electrodes 220 facing away from the diaphragm layer, for insulating and protecting the second electrodes 220. During operation of the ultrasonic transducer, the second electrode 220 above the diaphragm 240 and a part, whose orthographic projection on the driving backplane overlaps with that of the diaphragm 240 on the driving backplane, of the insulating protection layer 300 may vibrate together with the diaphragm 240, thereby performing ultrasonic transmission and reception. In specific implementations, the insulating protection layer 300 may be of a single-layer structure or a multi-layer structure. For example, as shown in FIG. 1, the insulating protection layer 300 may include a first insulating protection layer 310, a second planarization layer 320, and a second insulating protection layer 330. The materials of the first insulating protection layer 310 and the second insulating protection layer 330 may include at least one inorganic insulating material such as silicon nitride (SiN), silicon dioxide (SiO₂), or silicon oxynitride (SiON). The second planarization layer 320 may be an organic insulating material such as resin, which is not limited thereto.

As is well known to those skilled in the art, the ultrasonic transducer provided in the embodiments of the disclosure may further include other structures not mentioned above. In specific implementations, the structures not mentioned in the ultrasonic transducer provided in the embodiments of the disclosure may be referred to in the related art, and will not be repeated herein.

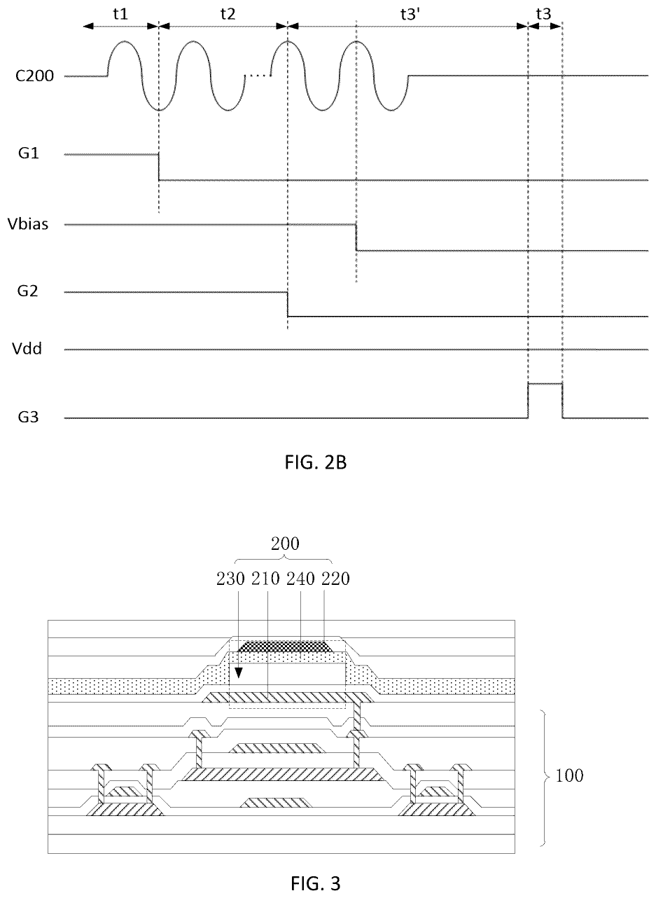

FIG. 2A is a schematic diagram of the driving circuit of a CMUT according to embodiments of the disclosure, and FIG. 2B is a timing chart for driving a CMUT according to embodiments of the disclosure.

In a specific embodiment, as shown in FIG. 2A, one driving circuit electrically connected with one transducer unit 200 includes a first transistor T1, a second transistor T2, a third transistor T3, a fourth transistor T4, and a storage capacitor CB.

A gate of the first transistor T1 is electrically connected with a first gate line G1, a first terminal of the first transistor T1 is electrically connected with a first voltage line Vbias, and a second terminal of the first transistor T1 is electrically connected with a first terminal of the second transistor T2. Here, the first terminal may be a source of the transistor and the second terminal may be a drain, or the second terminal may be the source and the first terminal may be the drain. This will not be repeated in the subsequent description.

A gate of the second transistor T2 is electrically connected with a second gate line G2, and a second terminal of the second transistor T2 is electrically connected with a gate of the third transistor T3.

A first terminal of the third transistor T3 is electrically connected with a second voltage line Vdd, and a second terminal of the third transistor T3 is electrically connected with a first terminal of the fourth transistor T4.

A gate of the fourth transistor T4 is electrically connected with a third gate line G3, and a second terminal of the fourth transistor T4 is electrically connected with a signal reading line Vread.

A first electrode of the storage capacitor CB is electrically connected with the second voltage line Vdd, and a second electrode of the storage capacitor CB is electrically connected with the gate of the third transistor T3.

A first electrode of the transducer unit 200 is electrically connected with the first terminal of the second transistor T2, and a second electrode of the transducer unit 200 is electrically connected with the driving voltage line Vda, where the driving voltage line Vda is used to input a DC voltage Vdc and an AC voltage Vac to the second electrode of the transducer unit 200.

To achieve fingerprint recognition, referring to FIG. 2B, the operation of the ultrasonic transducer may include the following phases.

In phase t1 (ultrasonic transmitting phase), both a DC voltage Vdc and an AC voltage Vac are applied to the second electrode of the transducer unit 200. The first transistor T1 and the second transistor T2 are turned on, the first voltage line Vbias is at a constant potential, and the diaphragm 240 of the transducer unit 200 vibrates at high frequency to emit sound waves.

In phase t2 (ultrasonic receiving phase), a DC voltage Vdc is applied to the left electrode of the transducer unit 200, and no AC voltage Vac is applied. The first transistor T1 is turned off, the second transistor T2 is turned on, sound waves reflected from the finger reach the transducer unit 200, causing the diaphragm 240 to vibrate and generate an alternating current (charge), and the charges are stored in the storage capacitor CB.

In phase t3 (reading phase), the third transistor T3 and the fourth transistor T4 are turned on, the charges stored in the storage capacitor CB are converted into current by the third transistor T3, and is finally output through the fourth transistor T4. The current is read through the signal reading line Vread to achieve fingerprint recognition.

In specific implementations, after collecting charges in phase t2, the reading operation in phase t3 may not be performed immediately. That is, a buffer phase t3′ may be provided between phase t2 and phase t3, and the operation in phase t3 may be performed when reading is needed. In phase t3′, the voltage on the first voltage line Vbias may be pulled down to reduce power consumption.

It should be noted that the driving circuit and timing shown in FIG. 2A and FIG. 2B are used for illustrating one specific embodiment to illustrate the operation process of the CMUT. The driving circuit in the embodiments of the disclosure is not limited to the structure shown in FIG. 2A. Other circuits that can be combined with the CMUT provided in the embodiments of the disclosure to realize ultrasonic fingerprint recognition are also within the protection scope of the embodiments of the disclosure. In addition, the ultrasonic transducer provided in the embodiments of the disclosure can not only be used for fingerprint recognition, but also for touch functions, gesture recognition, medical ultrasonic imaging, underwater detection, and other functions, and is not limited thereto.

FIG. 3 is a cross-sectional view of a CMUT in the related art.

For CMUTs fabricated on glass or PI substrates using display semiconductor processes, there are typically process variations of about ±2% in planar dimensions and about ±10% in thickness direction. These dimensional variations may cause the resonant frequency of the actually fabricated diaphragm 240 to shift compared to the resonant frequency of the diaphragm 240 with designed dimensions. Since CMUTs in the related art typically use a global emission mode to apply emission signals to each transducer unit 200, meaning the voltage signals applied between the first and second electrodes are the same for all transducer units 200 and match the vibration frequency of the diaphragm 240 with designed dimensions, the diaphragms 240 whose actual dimensions deviate from the designed dimensions operate at a mismatched vibration frequency, resulting in weakened vibration of the diaphragm 240 and signal attenuation. In some technical approaches, as shown in FIG. 3, one resonant cavity 230 is provided in one transducer unit 200. If the dimension of the diaphragm 240 of each transducer unit 200 in the CMUT deviates, it can lead to up to 90% signal attenuation, seriously affecting the performance of the CMUT.

In the ultrasonic transducer provided by the embodiments of the disclosure, a plurality of cavities 230 which are spaced apart from each other are provided between the first electrode 210 and the second electrode 220 of each transducer unit 200. Accordingly, each transducer unit 200 has a plurality of diaphragms 240 corresponding one-to-one with the cavities 230. During the ultrasonic emission and reception phases, the plurality of diaphragms 240 in each transducer unit 200 vibrate together to emit or receive ultrasonic waves. Compared to the case where each transducer unit 200 is provided with one resonant cavity, even if the dimensions of the diaphragms 240 may still have process deviations, the signal strength can be greatly increased due to the increased number of diaphragms 240, reducing the impact of process deviations on the performance of the CMUT.

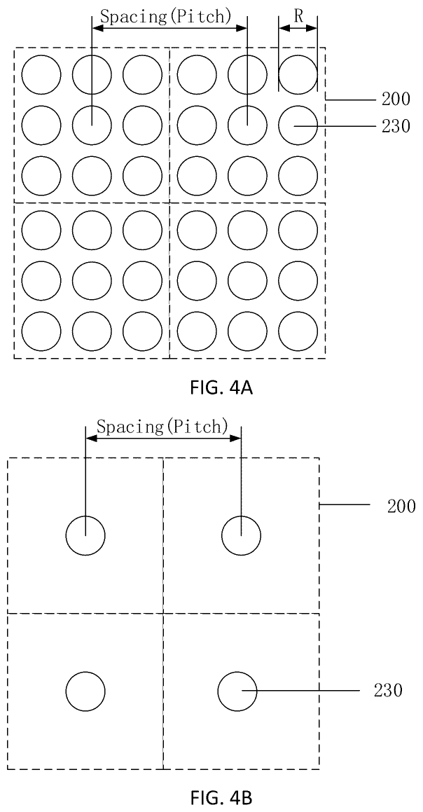

FIG. 4A is a top view of a CMUT according to embodiments of the disclosure, and FIG. 4B is a top view of a CMUT in the related art.

For example, when applied to fingerprint recognition, to distinguish between signals of fingerprint valley and ridge, a pitch between centers of two adjacent transducer units 200 is usually designed to be less than 80 μm, and cannot exceed 100 μm at maximum. The one-side dimension of one resonant cavity 230 is usually 20 μm to 30 μm. It should be noted that, in the embodiments of the disclosure, the size of the resonant cavity 230 specifically refers to the planar dimensions of the orthographic projection of the resonant cavity 230 on the plane where the driving backplane 100 is located. For example, if the orthographic projection of the resonant cavity 230 on the driving backplane 100 is circular, the size of the resonant cavity 230 specifically refers to the diameter or radius of this circle. If the orthographic projection of the resonant cavity 230 on the driving backplane 100 is rectangular, the size of the resonant cavity 230 specifically refers to the length and width of this rectangle. During specific implementation, the orthographic projection of the resonant cavity 230 on the driving backplane 100 can be other shapes, which is not limited herein.

Taking the pitch between the centers of two adjacent transducer units 200 as 75 μm and the size R of the resonant cavity 230 (taking a circular resonant cavity as an example, R is the diameter of the resonant cavity; the resonant cavity can be other shapes in actual implementation) as 20 μm, as shown in FIG. 4A, if the CMUT includes a plurality of transducer units 200 arranged in an array, and the resonant cavities 230 in the transducer unit 200 are arranged in an array along the directions of the array of transducer units 200. 9 resonant cavities 230 arranged along the row and column directions of the array can be provided in one transducer unit 200. Compared to FIG. 4B where only one resonant cavity 230 is provided in one transducer unit 200, a charge quantity, close to 9 times the amount based on FIG. 4B, can be obtained based on FIG. 4A in an ideal case. Considering the voltage division of the drive circuit, a charge quantity close to 5 times the amount based on FIG. 4B can be obtained. Further considering the approximately 30% signal attenuation caused by process deviations, based on the arrangement shown in FIG. 4A, the signal strength about 3.5 times that that obtained based on the arrangement in FIG. 4B can be actually obtained, significantly increasing the signal strength and improving the performance of the CMUT.

Moreover, as the quantity of diaphragms 240 in one transducer unit 200 increases, the probability of a larger dimensional deviation occurring simultaneously in all diaphragms 240 of one transducer unit 200, causing the transducer unit 200 to fail, decreases. For example, if the probability of a large dimensional deviation occurring in one diaphragm 240 is 1/10, then the probability of two diaphragms 240 simultaneously having a large dimensional deviation is 1/100, and the probability for four diaphragms 240 is 1/10000. Thus, providing more diaphragms 240 in one transducer unit 200 can greatly improve process stability and reduce the sensitivity of CMUT performance to the fabrication process. It should be noted that the probability of a large dimensional deviation occurring in one diaphragm mentioned above is only for exemplary explanation of the embodiments of the disclosure and does not represent a limitation on the actual probability.

In some embodiments, within the same transducer unit 200, the sizes of the plurality of resonant cavities 230 are the same, and the plurality of resonant cavities 230 are arranged in an array.

In some embodiments, within the same transducer unit 200, the sizes of at least some of the plurality of resonant cavities 230 are different. Specifically, during the design of the ultrasonic transducer, one transducer unit 200 can be designed to have multiple resonant cavities 230 of different sizes. Without considering process deviations, since the sizes of the resonant cavities 230 are different, the diaphragms 240 corresponding to each resonant cavity 230 also have different sizes. Diaphragms 240 of different sizes have different resonant frequencies, enabling the ultrasonic transducer to operate at a plurality of frequencies, thereby increasing the bandwidth of the ultrasonic transducer.

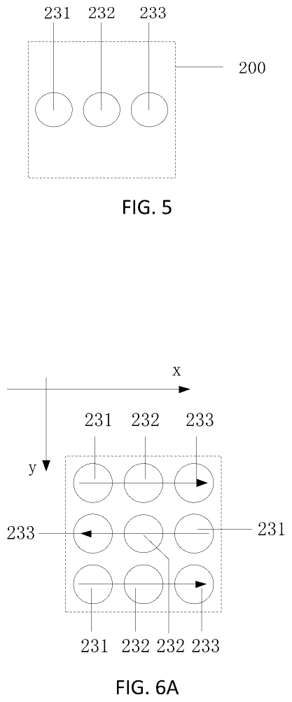

FIG. 5 is a second top view of a CMUT according to embodiments of the disclosure.

In some embodiments, as shown in FIG. 5, within the same transducer unit 200, the plurality of resonant cavities 230 can include at least one first resonant cavity 231, at least one second resonant cavity 232, and at least one third resonant cavity 233. The size of the first resonant cavity 231 is larger than the size of the second resonant cavity 232, and the size of the second resonant cavity 232 is larger than the size of the third resonant cavity 233. The first resonant cavity 231 corresponds to a first diaphragm with a resonant frequency of a first frequency. The second resonant cavity 232 corresponds to a second diaphragm with a resonant frequency of a second frequency. The third resonant cavity 233 corresponds to a third diaphragm with a resonant frequency of a third frequency. Without considering process fluctuations, sufficient signal strength can be obtained through the vibration of the first diaphragm, second diaphragm, or third diaphragm. Thus, the CMUT can have three operating frequencies: the first frequency, the second frequency, and the third frequency, which can greatly expand the application scenarios of the CMUT. Considering process fluctuations, even if the signal generated by a diaphragm of a certain size attenuates, it can be compensated by the vibrations of the diaphragms of the other two sizes, thereby meeting the normal operation requirements of the CMUT. For example, when the CMUT operates at the second frequency, even if the vibration of the second diaphragm weakens due to process deviations, the signal strength can be compensated to a certain extent by the vibrations of the first and third diaphragms, ensuring the normal operation of the CMUT.

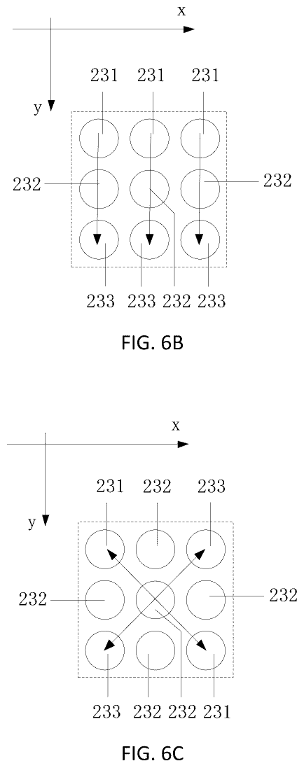

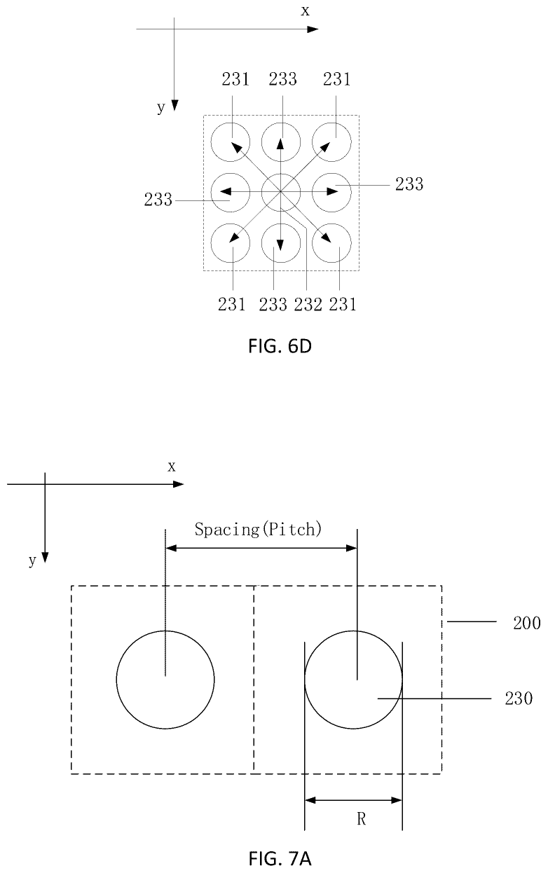

In some embodiments, any two of the first resonant cavity 231 and the third resonant cavity 233 are arranged in pairs at both sides of the second resonant cavity 232. Specifically, as shown in FIG. 5, if a same transducer unit 200 includes one first resonant cavity 231, one second resonant cavity 232, and one third resonant cavity 233, then the first resonant cavity 231 and the third resonant cavity 233 can be arranged at both sides of the second resonant cavity 232, respectively. If a same transducer unit 200 includes a plurality of first resonant cavities 231 and a plurality of third resonant cavities 233, during specific implementation, one first resonant cavity 231 and one second resonant cavity 233 can be arranged in pairs at both sides of the second resonant cavity 232 (specifically refer to FIGS. 6A, 6B, and 6C); or two resonant cavities of the same size can be arranged in pairs at both sides of the second resonant cavity 232, for example, two first resonant cavities 231 arranged in pairs at both sides of the second resonant cavity 232 or two third resonant cavities arranged in pairs at both sides of the second resonant cavity 232 (specifically refer to FIGS. 6C and 6D), which is not limited herein.

During specific implementation, the second frequency can be set as the primary operating frequency, meaning the ultrasonic transducer operates at the second frequency for emitting and receiving ultrasonic waves in most working scenarios and most of the time. Any two of the first resonant cavity 231 and the third resonant cavity 233 in pairs are arranged at both sides of the second resonant cavity 232, and in this case, when the ultrasonic transducer operates at the primary operating frequency (the second frequency), the vibration amplitude of the second diaphragm corresponding to the second resonant cavity 232 is the largest, while the vibration amplitudes of the first diaphragm corresponding to the first resonant cavity 231 and the third diaphragm corresponding to the third resonant cavity 233 at both sides of the second resonant cavity 232 are relatively smaller. The intensity of the ultrasonic signal is concentrated at the center of each transducer unit 200, which is beneficial for improving the uniformity and positional accuracy of the ultrasonic signals emitted and received by the ultrasonic transducer at the primary operating frequency.

During specific implementation, a shape of the orthographic projection of the resonant cavity 230 on the driving backplane 100 can be a regular shape, for example, the shape of the orthographic projection of the resonant cavity 230 on the driving backplane 100 can be circular, rectangular, square, diamond, etc. During specific implementation, centers of the resonant cavities arranged in pairs at both sides of the second resonant cavity 232 can be made symmetric about the center of the second resonant cavity 232 to further improve signal uniformity. For example, one first resonant cavity 231 and one third resonant cavity 233 are arranged in pairs at both sides of a second resonant cavity 232. Specifically, the center of this first resonant cavity 231 and the center of this third resonant cavity 233 can be made symmetric about the center of this second resonant cavity 232. The center of the resonant cavity specifically can be a geometric center of the orthographic projection of the resonant cavity 230 on the driving backplane 100, which is not limited herein.

FIG. 6A is a third top view of a CMUT according to embodiments of the disclosure, FIG. 6B is a fourth top view of a CMUT according to embodiments of the disclosure, FIG. 6C is a fifth top view of a CMUT according to embodiments of the disclosure, and FIG. 6D is a sixth top view of a CMUT according to embodiments of the disclosure.

During specific implementation, as shown in FIGS. 6A to 6D, within one transducer unit 200, a plurality of resonant cavities 230 are arranged in a three-by-three array. The resonant cavity 230 at least located at the center of the array is the second resonant cavity 232.

In some embodiments, as shown in FIG. 6A, within one transducer unit 200, a plurality of resonant cavities 230 are arranged in a three-by-three array. In a first row of this array, a first resonant cavity 231, a second resonant cavity 232, and a third resonant cavity 233 are sequentially arranged along the row direction x of the array. In a second row of the array, a first resonant cavity 231, a second resonant cavity 232, and a third resonant cavity 233 are sequentially arranged along a direction that is opposite to that of the first row. In a third row of the array, a first resonant cavity 231, a second resonant cavity 232, and a third resonant cavity 233 are sequentially arranged in the direction that is same to that of the first row.

In some embodiments, as shown in FIG. 6B, within one transducer unit 200, a plurality of resonant cavities 230 are arranged in a three-by-three array. Sizes of a plurality of resonant cavities 230 located in a same row of the array are the same. In a same column of the array, a first resonant cavity 231, a second resonant cavity 232, and a third resonant cavity 233 are sequentially arranged along the column direction of the array.

In some embodiments, as shown in FIG. 6C, within one transducer unit 200, a plurality of resonant cavities 230 are arranged in a three-by-three array. In this array, a middle position of each row is used for setting a second resonant cavity 232, and a middle position of each column is used for setting a second resonant cavity 232. Two first resonant cavities 231 are arranged, symmetrically about the second resonant cavity 232 located at the center of the array, in pairs on two diagonals of the array, and two third resonant cavities 233 are arranged, symmetrically about the second resonant cavity 232 located at the center of the array, in pairs on the remaining two diagonals of the array; or, one first resonant cavity 231 and one third resonant cavity 233 are arranged symmetrically about the second resonant cavity 232 located at the center of the array, in pairs on two diagonals of the array, and the other first resonant cavity 231 and the other third resonant cavity 233 are arranged, symmetrically about the second resonant cavity 232 located at the center of the array, in pairs on the remaining two diagonals of the array.

In some embodiments, as shown in FIG. 6D, within one transducer unit 200, a plurality of resonant cavities 230 are arranged in a three-by-three array. One second resonant cavity 232 is located at the center of the array. First resonant cavities 231 and third resonant cavities 233 are distributed around the second resonant cavity 232, and disposed spaced apart from each other.

In the embodiments shown in FIGS. 6A to 6D, x indicates the row direction of the array, and y indicates the column direction of the array. In other embodiments, x can indicate the column direction of the array, and y can indicate the row direction of the array, which is not limited herein.

When designing the size of the resonant cavities 230, the sizes of the first resonant cavity 231, the second resonant cavity 232, and the third resonant cavity 233 can be determined based on the range of dimensional errors caused by process fluctuations. For example, typically, the error range for the size R of resonant cavities due to process fluctuations in display semiconductors is ±0.6 μm. When designing the size of the resonant cavities 230, the difference between the size of the second resonant cavity 232 and the size of the first resonant cavity 231, and the difference between the size of the third resonant cavity 233 and the size of the second resonant cavity 232, can both be made less than or equal to 0.6 μm. Specifically, the difference between the size of the second resonant cavity 232 and the size of the first resonant cavity 231, and the difference between the size of the third resonant cavity 233 and the size of the second resonant cavity 232, can both be designed to be half of the error caused by process fluctuations. When the error range caused by process fluctuations is ±0.6 μm, the difference between the size of the second resonant cavity 232 and the size of the first resonant cavity 231, and the difference between the size of the third resonant cavity 233 and the size of the second resonant cavity 232, can both be 0.3 μm, so that the size deviation of the first and third diaphragms from the second diaphragm is small, and their center frequencies are close, ensuring that the ultrasonic signals emitted and received by the ultrasonic transducer have greater signal strength. During specific implementation, by reasonably setting the sizes and arrangement of the first resonant cavity 231, the second resonant cavity 232, and the third resonant cavity 233, the center frequencies of vibration of the first, second, and third resonant cavities 233 are made close and overlap within the frequency range of −3 dB, allowing the main peak of the transducer unit to transition smoothly and increasing the bandwidth of the CMUT. During specific implementation, if the cavity bandwidth is too narrow or the process deviation is too large, and no overlap within the frequency range −3 dB is achieved, compensation can be made by reducing the size difference between the resonant cavities or increasing the size of the resonant cavity. For example, when designing the size of the resonant cavity, one-quarter of the error caused by process fluctuations is added to or subtract from the second cavity size to obtain the design sizes of the first resonant cavity and the third cavity, respectively. Taking the transducer unit 200 shown in FIG. 5 as an example, the diameter of the second resonant cavity 232 can be 20 μm, the diameter of the first resonant cavity 231 can be 19.5 μm, and the diameter of the third resonant cavity 233 can be 20.5 μm, which is not limited herein.

It should be noted that in the embodiments of the disclosure, the difference between the size of the second resonant cavity 232 and the size of the first resonant cavity 231, and the difference between the size of the third resonant cavity 233 and the size of the second resonant cavity 232, are both described without considering the influence of process fluctuations. In actual implementation, due to the influence of process errors, the difference between the size of the second resonant cavity 232 and the size of the first resonant cavity 231, and the difference between the size of the third resonant cavity 233 and the size of the second resonant cavity 232 may differ from the design values. Taking circular resonant cavities as an example, the design diameter of the second resonant cavity 232 can be 20 μm, the design diameter of the first resonant cavity 231 can be 19.5 μm, and the design diameter of the third resonant cavity 232 can be 20.5 μm. Considering the process fluctuation error of 0.6 μm, the actual range of the difference between the diameter of the second resonant cavity 232 and the diameter of the first resonant cavity 231 is −0.7 μm to 1.7 μm, and the range of the difference between the diameter of the third resonant cavity 233 and the diameter of the second resonant cavity 232 is 0.7 μm to 1.7 μm. During specific implementation, the actual magnitudes of the difference between the size of the second resonant cavity 232 and the size of the first resonant cavity 231, and the difference between the size of the third resonant cavity 233 and the size of the second resonant cavity 232 vary according to the specific situation and are not limited herein.

In some embodiments, within one transducer unit 200, a plurality of resonant cavities 230 are arranged in a plurality of rows, and the resonant cavities 230 located in two adjacent rows are arranged in a staggered manner. The difference between this arrangement and the array arrangement of resonant cavities 230 shown in FIGS. 6A to 6D is that, for the resonant cavities 230 arranged in an array, a quantity of columns of resonant cavities 230 is the same as a quantity of resonant cavities 230 included in a same row, whereas in the arrangement where resonant cavities 230 in adjacent rows are arranged in the staggered manner, the quantity of columns of the resonant cavities 230 is a sum of the quantities of resonant cavities 230 in two adjacent rows. Arranging a plurality of resonant cavities 230 in a plurality of rows with a staggered arrangement between adjacent rows is conducive to setting a larger quantity of resonant cavities 230 in a transducer unit 200 of the same size, thereby further increasing the signal strength.

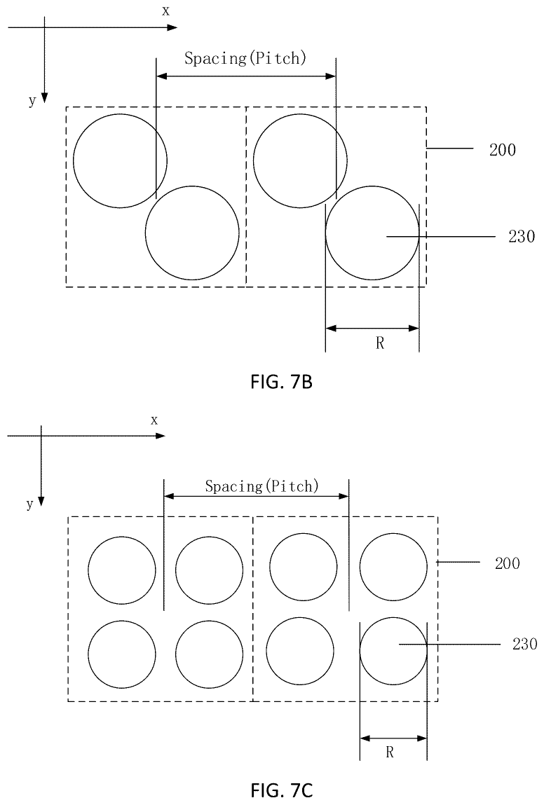

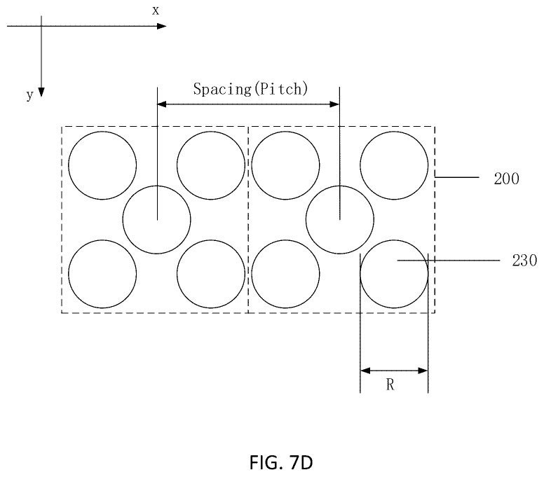

FIG. 7A is a seventh top view of a CMUT according to embodiments of the disclosure, FIG. 7B is an eighth top view of a CMUT according to embodiments of the disclosure, FIG. 7C is a ninth top view of a CMUT according to embodiments of the disclosure, and FIG. 7D is a tenth top view of a CMUT according to embodiments of the disclosure.

For example, in some embodiments, as shown in FIGS. 7A and 7B, a spacing Pitch between two adjacent transducer units 200 is 50 μm, and the size R of the resonant cavity 230 (taking a circular resonant cavity as an example, R is the diameter of the resonant cavity; the resonant cavity can be other shapes in actual implementation) is 26 μm. As shown in FIG. 7A, when arranged in an array, only one resonant cavity 230 can be set in the one transducer unit 200; as shown in FIG. 7B, when the resonant cavities 230 are arranged in a plurality of rows with a staggered arrangement between adjacent rows, two resonant cavities 230 can be set simultaneously in the one transducer unit 200.

In some embodiments, as shown in FIGS. 7C and 7D, the spacing Pitch between two adjacent transducer units 200 is 55 μm, and the size R of the resonant cavity 230 (taking a circular resonant cavity as an example, R is the diameter of the resonant cavity; the resonant cavity can be other shapes in actual implementation) is 20 μm. As shown in FIG. 7C, when arranged in an array, four resonant cavities 230 arranged in two rows and two columns can be set in one transducer unit 200; as shown in FIG. 7D, when the resonant cavities 230 are arranged in a plurality of rows with a staggered arrangement between adjacent rows, five resonant cavities 230 arranged in three rows can be set simultaneously in one transducer unit 200. The first row and the third row each include two resonant cavities 230, and the second row includes one resonant cavity 230. During specific implementation, the resonant cavity 230 located in the second row among the five resonant cavities 230 can be set as the second resonant cavity, and the first and third resonant cavities can be distributed around the second resonant cavity and spaced apart from each other, which is not limited herein.

In the embodiments shown in FIGS. 7A to 7D, x indicates the row direction in which the resonant cavities are arranged, and y indicates the column direction in which the resonant cavities are arranged. In other embodiments, x can indicate the column direction in which the resonant cavities are arranged, and y can indicate the row direction in which the resonant cavities are arranged, which is not limited herein. In the embodiments shown in FIGS. 7A to 7D, the sizes of the various resonant cavities 230 within the same transducer unit are the same for illustrative purposes. During specific implementation, when the sizes of the various resonant cavities 230 within the same transducer unit are not identical, the staggered arrangement of resonant cavities in adjacent rows can also be adopted, which is not limited herein.

In some embodiments, the spacing between two adjacent resonant cavities 230 within a same transducer unit 200 is smaller than a spacing between resonant cavities 230 in two adjacent transducer units 200, to increase the spacing between resonant cavities 230 in adjacent transducer units 200 and avoid crosstalk of sound waves between adjacent transducer units 200. During specific implementation, the spacing between two resonant cavities 230 can be a distance between the centers of the two resonant cavities 230 or a minimum distance between edges of the two resonant cavities 230, which is not limited herein.

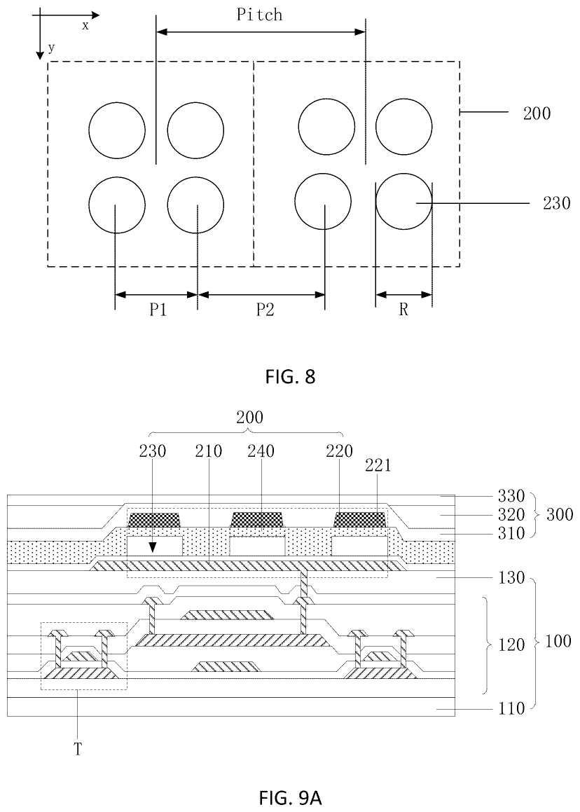

FIG. 8 is an eleventh top view of a CMUT according to embodiments of the disclosure.

For example, as shown in FIG. 8, the spacing Pitch between centers of two adjacent transducer units 200 is 80 μm, the size R of the resonant cavity 230 is 20 μm, the spacing P1 between the centers of two adjacent resonant cavities 230 in the same transducer unit 200 is 30 μm, and the minimum distance P2 between the centers of two resonant cavities 230 located respectively in two adjacent transducer units 200 is 50 μm. During specific implementation, under the condition of ensuring the strength of the diaphragm corresponding to each resonant cavity 230 in the same transducer unit 200, the spacing between two adjacent resonant cavities 230 in the same transducer unit 200 can be minimized as much as possible, thereby increasing the spacing between resonant cavities 230 located respectively in adjacent transducer units 200 and avoiding crosstalk of sound waves between adjacent transducer units 200.

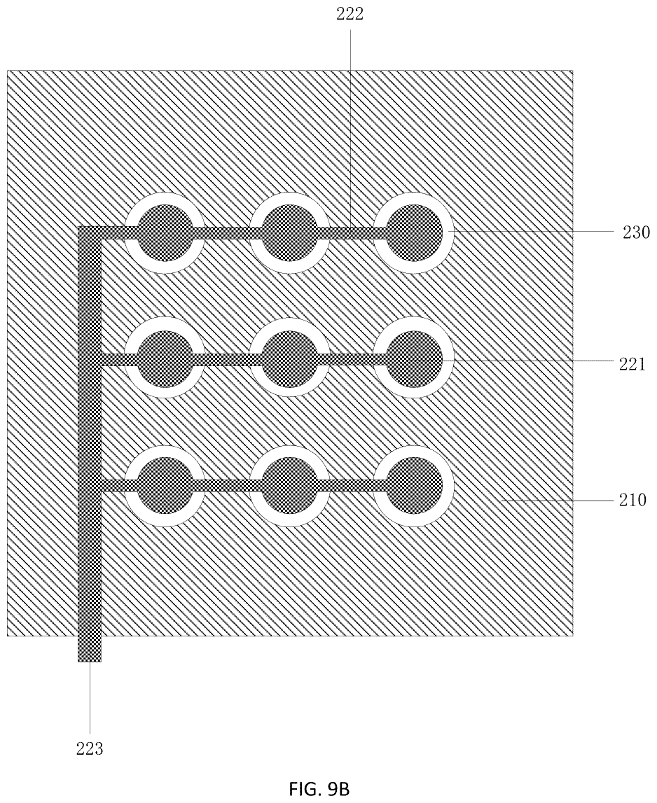

FIG. 9A is a second cross-sectional view of a CMUT according to embodiments of the disclosure, and FIG. 9B is a twelfth top view of a CMUT according to embodiments of the disclosure.

In some embodiments, as shown in FIGS. 9A and 9B, the second electrode 220 includes a plurality of second electrode sub-portions 221 which are spaced apart from each other. Here, “spaced apart” specifically means that the second electrode sub-portions 221 are separated by a certain distance in space, and does not limit the connection relationship between them. One second electrode sub-portion 221 corresponds to one resonant cavity 230. An orthographic projection of the second electrode sub-portion 221 on the driving backplane 100 overlaps with the orthographic projection of the corresponding resonant cavity 230 on the driving backplane 100. During specific implementation, the orthographic projection of the second electrode sub-portion 221 on the driving backplane 100 can be located within the orthographic projection of the corresponding resonant cavity 230 on the driving backplane 100, which is not limited herein. The plurality of second electrode sub-portions 221 are electrically connected via a first connection line 222. Dividing the second electrode 220 into a plurality of second electrode sub-portions 221 is conductive to reducing the overlapping area between the second conductive layer where the second electrode 220 is located and the first conductive layer where the first electrode 210 is located, compared to setting the second electrode 220 over the entire surface in one transducer unit 200. This reduces the parasitic capacitance generated by unnecessary overlap between the first and second conductive layers and improves the accuracy of the ultrasonic transducer.

In some embodiments, as shown in FIG. 9B, all the second electrode sub-portions 221 located in the same transducer unit 200 can be connected to the same first signal line 223 via the first connection line 222, so that the same drive signal can be input to all the second electrode sub-portions 221 in the same transducer unit 200 through this first signal line 223 for driving. During specific implementation, the first signal line 223 includes the drive voltage line Vda.

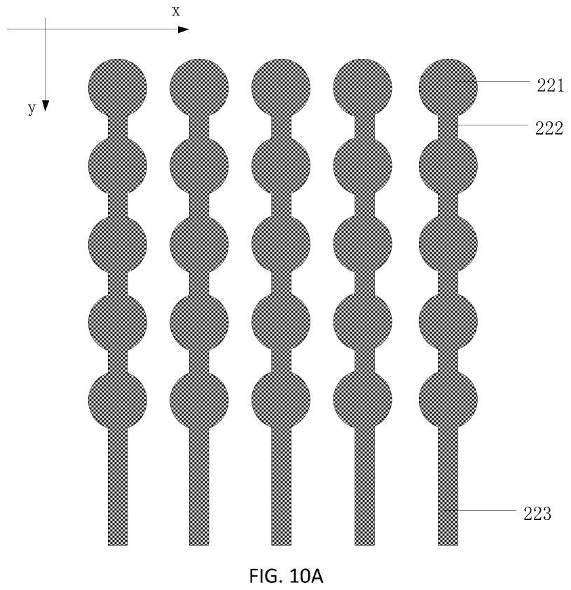

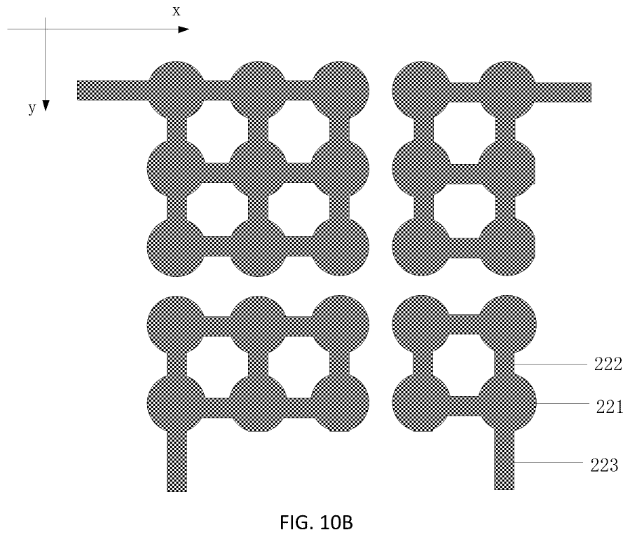

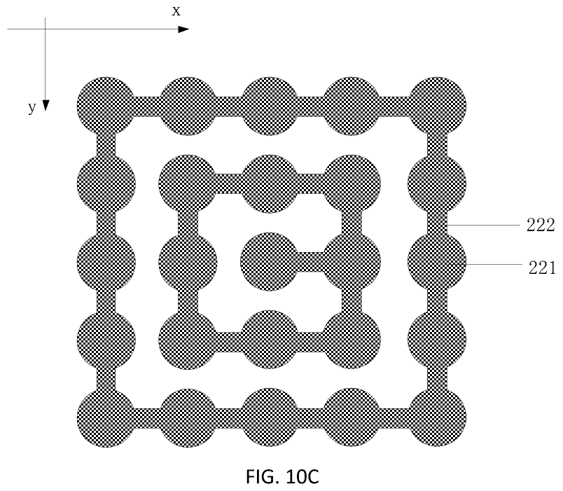

FIG. 10A is a thirteenth top view of a CMUT according to embodiments of the disclosure; FIG. 10B is a fourteenth top view of a CMUT according to embodiments of the disclosure; and FIG. 10C is a fifteenth top view of a CMUT according to embodiments of the disclosure.

In the embodiments of the present invention, one transducer unit 200 can include a plurality of resonant cavities 230. The greater the quantity of resonant cavities 230 and the larger the size of the transducer unit 200, the greater the possible size difference between resonant cavities 230 located in different regions of the same transducer unit 200. For example, as the quantity of resonant cavities 230 increases, the resonant cavities 230 located at opposite diagonal regions of the transducer unit 200 may have significant size differences due to the large distance. Therefore, during specific implementation, power supply can be provided based on different regions. The second electrode 220 of one transducer unit 200 is divided into a plurality of connection regions. The size differences caused by process fluctuations between the various resonant cavities 230 within the same connection region are small. The second electrode sub-portions 221 within the same connection region are connected via the first connection line 222 and connected to the same first signal line 223, to be provided with the same voltage signal. The various resonant cavities 230 located in different connection regions may have significant size differences due to process fluctuations. During specific implementation, the second electrode sub-portions 221 in different connection regions are insulated from each other. The second electrode sub-portions 221 in different regions are connected to different first signal lines 223 to be provided with voltage signals matching the sizes of the resonant cavities 230 in each connection region, so that the diaphragms 240 in different connection regions within the same transducer unit 200 all operate at suitable frequencies to improve the strength of the ultrasonic signal. During specific implementation, the first signal line 223 includes the drive voltage line Vda.

In some embodiments, as shown in FIG. 10A, the second electrode sub-portions 221 located in the same column can be connected in series via the first connection line 222, and the second electrode sub-portions 221 in the same column that are connected in series are connected to the same first signal line 223; the second electrode sub-portions 221 located in different columns are connected to different first signal lines 223.

In some embodiments, as shown in FIG. 10B, the same second electrode 220 can be divided into a plurality of connection regions along the diagonal directions. Specifically, the second electrode 220 can be divided into two opposite connection regions, or as shown in FIG. 10B, the second electrode 220 can be divided into four opposite connection regions. The second electrode sub-portions 221 located in the same connection region are connected via the first connection line 222 and connected to the same first signal line 223. The second electrode sub-portions 221 located in different connection regions are connected to different first signal lines 223.

In some embodiments, as shown in FIG. 10C, the same second electrode 220 can be divided into a plurality of connection regions from the inside to the outside. Specifically, the second electrode 220 can be divided into an internal connection region and an external connection region; the second electrode sub-portions 221 located in the same connection region are connected via the first connection line 222 and connected to the same first signal line. The second electrode sub-portions 221 located in different connection regions are connected to different first signal lines.

In the embodiments shown in FIGS. 10A to 10C, x indicates the row direction in which the resonant cavities are arranged, and y indicates the column direction in which the resonant cavities are arranged. In other embodiments, x can indicate the column direction in which the resonant cavities are arranged, and y can indicate the row direction in which the resonant cavities are arranged, which is not limited herein.

In some embodiments, as shown in FIG. 9B, within one transducer unit 200, the first electrode 210 is set over the entire surface to reduce process difficulty.

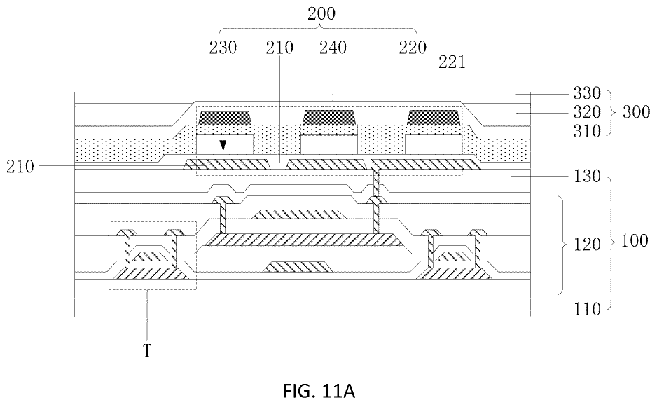

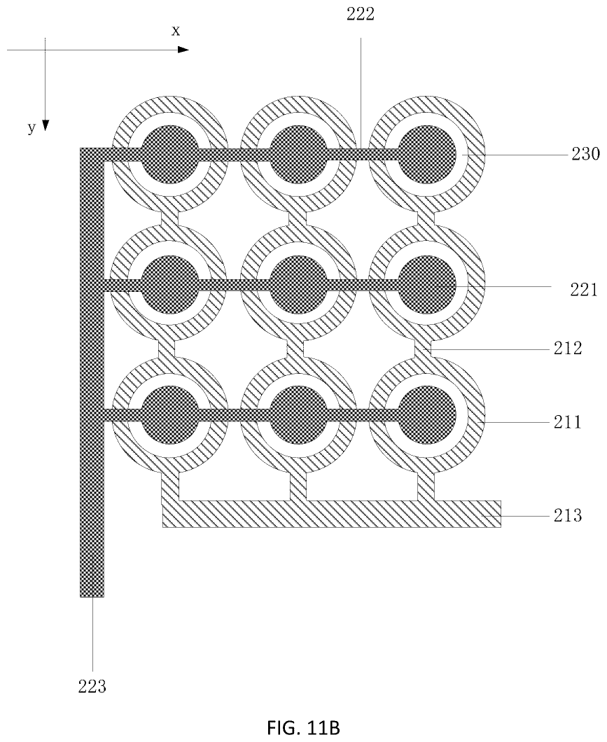

FIG. 11A is a third cross-sectional view of a CMUT according to embodiments of the disclosure; and FIG. 11B is a sixteenth top view of a CMUT according to embodiments of the disclosure.

In some embodiments, as shown in FIGS. 11A and 11B, the first electrode 210 includes a plurality of first electrode sub-portions 211 spaced apart from each other. Here, “spaced apart” specifically means that the first electrode sub-portions 211 are separated by a certain distance in space, and does not limit the connection relationship between them. One first electrode sub-portion 211 corresponds to one resonant cavity 230. An orthographic projection of the first electrode sub-portion 211 on the driving backplane 100 overlaps with the orthographic projection of the corresponding resonant cavity 230 on the driving backplane 100. During specific implementation, the orthographic projection of the resonant cavity 230 on the driving backplane 100 can be located within the orthographic projection of the corresponding first electrode sub-portion 211 on the driving backplane 100, which is not limited herein. Dividing the first electrode 210 into a plurality of first electrode sub-portions 211 is conductive to reducing the overlapping area between the first conductive layer where the first electrode 210 is located and the second conductive layer where the second electrode 220 is located. This reduces the parasitic capacitance generated by unnecessary overlap between the first and second conductive layers and improves the accuracy of the ultrasonic transducer.

During specific implementation, the plurality of first electrode sub-portions 211 in the first electrode 210 are electrically connected via a second connection line 212. As shown in FIG. 11B, all the first electrode sub-portions 211 located in the same transducer unit 200 can be connected to the same second signal line 213 via the second connection line 212. During specific implementation, the second signal line 213 can include the first voltage line Vbias and the signal readout line Vread.

In the embodiments shown in FIGS. 2A-2B, 9A-10C, and 11A-11B, the electrode connection method of the CMUT provided by the embodiments of the disclosure is described taking the example where the second electrode 220 is connected to the drive voltage line Vda. In some embodiments, the first electrode 210 can be connected to the drive voltage line Vda, and the various first electrode sub-portions 211 in the first electrode 210 can also be connected using the partitioning method shown in FIGS. 10A-10C, which will not be repeated here.

In the ultrasonic transducer provided by the embodiments of the disclosure, it is possible to only set the first electrode 210 to include a plurality of first electrode sub-portions 211, with the second electrode 220 set over the entire surface; or only set the second electrode 220 to include a plurality of second electrode sub-portions 221, with the first electrode 210 set over the entire surface; or simultaneously set the first electrode 210 to include a plurality of first electrode sub-portions 211 and the second electrode 220 to include a plurality of second electrode sub-portions 221, which is not limited herein.

In some embodiments, the first electrode 210 includes a plurality of first electrode sub-portions 211, and the second electrode 220 includes a plurality of second electrode sub-portions 221. An extension direction of the second connection line 212 for connecting the first electrode sub-portions 211 and an extension direction of the first connection line 222 for connecting the second electrode sub-portions 221 intersect with each other, which can further reduce the overlapping area between the first connection line 222 and the second connection line 212, and reduce the parasitic capacitance generated between them.

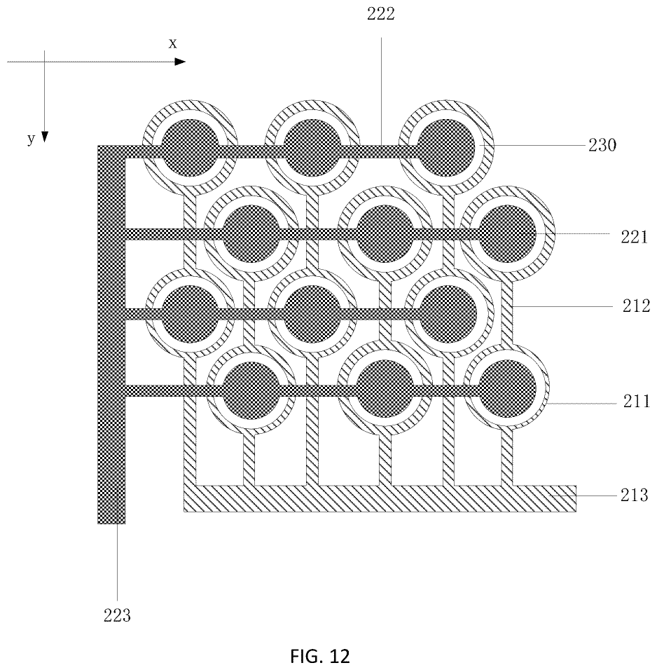

FIG. 12 is a seventeenth top view of a CMUT according to embodiments of the disclosure.

In some embodiments, within one transducer unit 200, a plurality of resonant cavities 230 are arranged in a plurality of rows and a plurality of columns. Here, the arrangement of the plurality of resonant cavities 230 in the plurality of rows and columns can be an array as shown in FIG. 11B, or a staggered arrangement of resonant cavities 230 in adjacent rows forming the plurality of rows and columns as shown in FIG. 12, which is not limited herein. During specific implementation, the first connection lines 222 connect the second electrode sub-portions 221 located in the same row along the row direction of the plurality of resonant cavities 230; the second connection lines 212 connect the first electrode sub-portions 211 located in the same column along the column direction of the plurality of resonant cavities 230, thereby causing the extension direction of the second connection lines 212 to intersect with the extension direction of the first connection lines 222, reducing the parasitic capacitance generated between the first connection lines 222 and the second connection lines 212.

In the embodiments shown in FIGS. 11B and 12, x indicates the row direction in which the resonant cavities are arranged, and y indicates the column direction in which the resonant cavities are arranged. In other embodiments, x can indicate the column direction in which the resonant cavities are arranged, and y can indicate the row direction in which the resonant cavities are arranged, which is not limited herein.

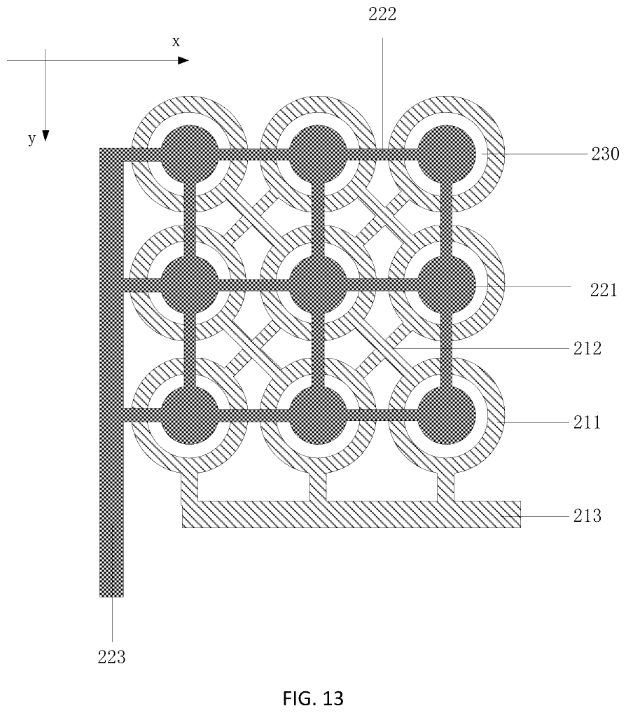

FIG. 13 is an eighteenth top view diagram of a CMUT according to embodiments of the disclosure.

In some embodiments, within one transducer unit 200, a plurality of resonant cavities 230 are arranged in a plurality of rows and columns. Here, the arrangement of the plurality of resonant cavities 230 in rows and columns can be an array as shown in FIG. 13, or a staggered arrangement of resonant cavities 230 in adjacent rows forming the rows and columns, which is not limited herein. During specific implementation, taking an array arrangement of the plurality of resonant cavities 230 as an example, as shown in FIG. 13, the first connection lines 222 connect the second electrode sub-portions 221 located in the same row along the row direction of the resonant cavities 230, and also connect the second electrode sub-portions 221 located in the same column along the column direction of the resonant cavities 230. The second connection lines 212 connect the first electrode sub-portions 211 arranged in a direction parallel to the diagonal direction of the resonant cavities 230, thereby causing the extension direction of the second connection lines 212 to intersect with the extension direction of the first connection lines 222, reducing the parasitic capacitance generated between the first connection lines 222 and the second connection lines 212. Furthermore, this can increase the connection channels between the second electrode sub-portions 221 and between the first electrode sub-portions 211, making the signal magnitude applied to each first electrode sub-portion 211 and second electrode sub-portion 221 more uniform.

In some embodiments, within one transducer unit 200, a plurality of resonant cavities 230 are arranged in a plurality of rows and columns. Here, the arrangement can be an array or a staggered arrangement of resonant cavities 230 in adjacent rows forming the rows and columns, which is not limited herein. The first connection lines 222 connect the second electrode sub-portions 221 arranged in a direction parallel to the diagonal direction of the plurality of resonant cavities 230; the second connection lines 212 connect the first electrode sub-portions 211 located in the same row along the row direction of the resonant cavities 230, and also connect the first electrode sub-portions 211 located in the same column along the column direction of the resonant cavities 230. During specific implementation, the connection method shown in FIG. 13 can be referred to, and no further details will be provided here.

In the embodiment shown in FIG. 13, x indicates the row direction in which the resonant cavities are arranged, and y indicates the column direction in which the resonant cavities are arranged. In other embodiments, x can indicate the column direction in which the resonant cavities are arranged, and y can indicate the row direction in which the resonant cavities are arranged, which is not limited herein.

The embodiments of the disclosure also provide a display panel. The display panel includes the ultrasonic transducer provided in any of the foregoing embodiments. During specific implementation, the display panel can be a Liquid Crystal Display (LCD) panel, an Organic Light Emitting Diode (OLED) display panel, a Light Emitting Diode (LED) display panel, a Micro Light Emitting Diode (Micro LED) display panel, etc., which is not limited herein. The ultrasonic transducer can be used to realize functions such as fingerprint recognition, gesture recognition, and touch operations for the display panel, which is not limited herein.

The display panel provided by the embodiments of the disclosure has the same or similar technical effects as the ultrasonic transducer provided in any of the foregoing embodiments, and no further details will be provided here.

The embodiments of the disclosure also provide a display device. The display device includes the display panel provided in any of the foregoing embodiments. The display device can be a mobile phone, tablet computer, laptop computer, etc., which is not limited herein. The display device provided by the embodiments of the disclosure has the same or similar technical effects as the display panel provided in any of the foregoing embodiments, and no further details will be provided here.

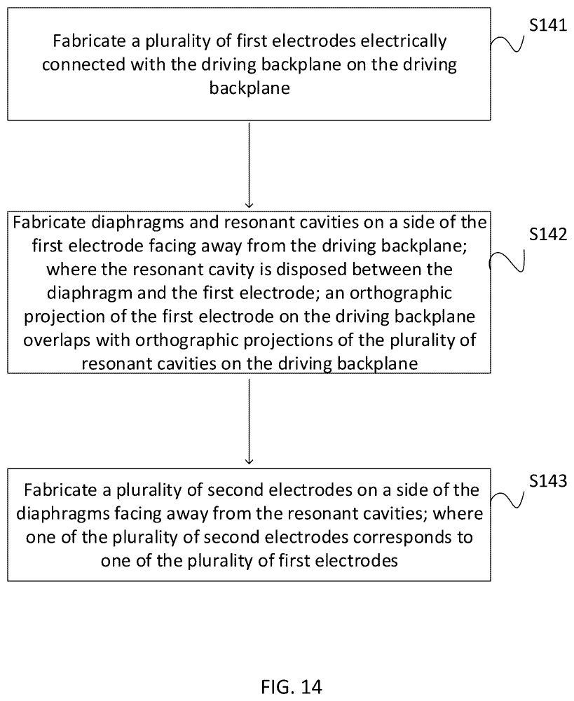

FIG. 14 is a flowchart of a method for fabricating an ultrasonic transducer according to embodiments of the disclosure.

The embodiments of the disclosure also provide a method for fabricating an ultrasonic transducer. As shown in FIG. 14, the method includes the following steps.

S141: fabricate a plurality of first electrodes electrically connected with the driving backplane on the driving backplane.

S142: fabricate diaphragms and resonant cavities on a side of the first electrode facing away from the driving backplane; where the resonant cavity is disposed between the diaphragm and the first electrode; an orthographic projection of the first electrode on the driving backplane overlaps with orthographic projections of the plurality of resonant cavities on the driving backplane.

S143: fabricate a plurality of second electrodes on a side of the diaphragms facing away from the resonant cavities; where one of the plurality of second electrodes corresponds to one of the plurality of first electrodes.

During specific implementation, in the fabrication method of the ultrasonic transducer provided by the embodiments of the disclosure, the fabrication of the driving backplane is completed first. Then, a plurality of first electrodes electrically connected with the driving backplane are fabricated on the driving backplane, where one drive electrode is used to form one transducer unit. After fabricating the first electrodes, the diaphragms and the resonant cavities are fabricated on the side of the first electrodes facing away from the driving backplane. The resonant cavity is disposed between the diaphragm and the first electrode. The orthographic projection of the first electrode on the driving backplane overlaps with the orthographic projections of the plurality of resonant cavities on the driving backplane. The diaphragms and resonant cavities can be fabricated using a process of etching a sacrificial layer. The specific method has been described in detail in the foregoing content and will not be repeated here. After forming the diaphragms and the resonant cavities, a plurality of second electrodes are fabricated on the side of the diaphragms facing away from the resonant cavities. One second electrode corresponds to one first electrode. The orthographic projection of the second electrode on the driving backplane overlaps with the orthographic projection of the corresponding first electrode on the driving backplane. One second electrode, the corresponding first electrode, and the diaphragms and resonant cavities disposed between the first electrode and the second electrode form one transducer unit.

The specific structure of the ultrasonic transducer has been described in detail in the embodiments of the disclosure. During specific implementation, the specific fabrication method of the ultrasonic transducer provided by the embodiments of the disclosure can refer to the specific structure of the aforementioned ultrasonic transducer, and no further details will be provided here.

Although preferred embodiments of the disclosure have been described, those skilled in the art will be able to make further changes and modifications to these embodiments once the basic inventive concepts are understood. Therefore, the appended claims are intended to be interpreted as including the preferred embodiments and all changes and modifications falling within the scope of the disclosure.

Apparently, those skilled in the art can make various changes and modifications to the embodiments without departing from the spirit and scope of the disclosure. Thus, if such modifications and variations of the embodiments fall within the scope of the appended claims and their equivalents, the disclosure also intends to encompass these changes and variations.

1. An ultrasonic transducer, comprising:
a driving backplane;
a plurality of transducer units on the driving backplane; each transducer unit comprising:
a first electrode disposed on the driving backplane and electrically connected with the driving backplane;
a second electrode disposed on a side of the first electrode facing away from the driving backplane;
a plurality of resonant cavities which are spaced apart from each other between the first electrode and the second electrode; and
a diaphragm disposed between the resonant cavity and the second electrode.

2. The ultrasonic transducer according to claim 1, wherein in the transducer unit, at least some of the plurality of resonant cavities have different sizes.

3. The ultrasonic transducer according to claim 2, wherein the plurality of resonant cavities comprises at least one first resonant cavity, at least one second resonant cavity, and at least one third resonant cavity;
a size of the first resonant cavity is larger than a size of the second resonant cavity, and the size of the second resonant cavity is larger than a size of the third resonant cavity.

4. The ultrasonic transducer according to claim 3, wherein two resonant cavities among the at least one first resonant cavity and the at least one third resonant cavity are arranged in pairs at both sides of the second resonant cavity.

5. The ultrasonic transducer according to claim 4, wherein in the transducer unit, the plurality of resonant cavities are arranged in an array with three rows and three columns; at least a resonant cavity located at a center of the array is the second resonant cavity.

6. The ultrasonic transducer according to claim 3, wherein a size difference between the second resonant cavity and the first resonant cavity is less than or equal to 0.6 μm; and
a size difference between the third resonant cavity and the second resonant cavity is less than or equal to 0.6 μm.

7. The ultrasonic transducer according to claim 2, wherein in the transducer unit, the plurality of resonant cavities are arranged in a plurality of rows, with resonant cavities in two adjacent rows being arranged in a staggered manner.

8. The ultrasonic transducer according to claim 1, wherein in the transducer unit, the plurality of resonant cavities are of a same size; and
the plurality of resonant cavities are arranged in an array; or
the plurality of resonant cavities are arranged in a plurality of rows, with resonant cavities in two adjacent rows being arranged in a staggered manner.

9. (canceled)

10. The ultrasonic transducer according to claim 1, wherein a spacing between two adjacent resonant cavities within a same transducer unit is smaller than a spacing between resonant cavities located respectively in two adjacent transducer units.

11. The ultrasonic transducer according to claim 1, wherein the second electrode comprises a plurality of second electrode sub-portions which are spaced apart from each other;
the second electrode sub-portions are electrically connected via a first connection line;
one of the plurality of second electrode sub-portions corresponds to one of the plurality of resonant cavities; and
an orthographic projection of the second electrode sub-portion on the driving backplane is located within an orthographic projection of a corresponding resonant cavity on the driving backplane.

12. The ultrasonic transducer according to claim 11, wherein the second electrode comprises a plurality of connection regions;
second electrode sub-portions within a same connection region are electrically connected with each other, and second electrode sub-portions in different connection regions are insulated from each other;
the second electrode sub-portions within the same connection region are electrically connected with a same first signal line, to allow a same signal to be provided to the second electrode sub-portions within that connection region.

13. The ultrasonic transducer according to claim 11, wherein in the transducer unit, the first electrode is formed across an entire surface.

14. The ultrasonic transducer according to claim 11, wherein the first electrode comprises a plurality of first electrode sub-portions which are spaced apart from each other;
one of the first electrode sub-portions corresponds to one of the plurality of resonant cavities;
an orthographic projection of the resonant cavity on the driving backplane is located within an orthographic projection of a corresponding first electrode sub-portion on the driving backplane; and
the plurality of first electrode sub-portions of the first electrode are connected to a same second signal line, to allow a same signal to be provided to the plurality of first electrode sub-portions of the first electrode.

15. The ultrasonic transducer according to claim 14, wherein the first electrode sub-portions are electrically connected via a second connection line; and
an extension direction of the first connection line and an extension direction of the second connection line intersect with each other.

16. The ultrasonic transducer according to claim 15, wherein in the transducer unit, the plurality of resonant cavities are arranged in a plurality of rows and a plurality of columns;
the first connection line connects, along a row direction of the plurality of resonant cavities, second electrode sub-portions located in a same row; and
the second connection line connects, along a column direction of the plurality of resonant cavities, first electrode sub-portions located in a same column.

17. The ultrasonic transducer according to claim 15, wherein in the transducer unit, the plurality of resonant cavities are arranged in a plurality of rows and a plurality of columns;
the first connection line connects, along a row direction of the plurality of resonant cavities, second electrode sub-portions located in a same row, and connects, along a column direction of the plurality of resonant cavities, second electrode sub-portions located in a same column;
the second connection line connects, along a diagonal direction of the plurality of resonant cavities, first electrode sub-portions arranged in a direction parallel to the diagonal direction.

18. The ultrasonic transducer according to claim 15, wherein in the transducer unit, the plurality of resonant cavities are arranged in a plurality of rows and a plurality of columns;
the first connection line connects, along a diagonal direction of the plurality of resonant cavities, second electrode sub-portions arranged in a direction parallel to the diagonal direction; and
the second connection line connects, along a row direction of the plurality of resonant cavities, first electrode sub-portions located in a same row, and connects, along a column direction of the plurality of resonant cavities, first electrode sub-portions located in a same column.

19. The ultrasonic transducer according to claim 1, wherein the driving backplane comprises a plurality of driving circuits;
one of the plurality of driving circuits corresponds to one of the plurality of transducer units, and the driving circuit is electrically connected with a corresponding transducer unit; and
the driving circuit comprises a thin film transistor.

20. The ultrasonic transducer according to claim 19, wherein the driving backplane further comprises a base substrate on a side of the plurality of driving circuits facing away from the plurality of transducer units; and
the base substrate is made of glass or polyimide.

21. A display panel, comprising the ultrasonic transducer according to claim 1.
